(19) United States
(12) Patent Application Publication
(10) Pub. No.: US 2006/0051887 A1
(43) Pub. Date: Mar. 9, 2006

(54) Manufacturing method and joining device for solid-state imaging devices

(75) Inventors: Kiyofumi Yamamoto, Minami-Ashigara-shi (JP); Kousuke Takasaki, Minami-Ashigara-shi (JP); Kazuo Okutsu, Minami-Ashigara-shi (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/218,553

(22) Filed: Sep. 6, 2005

(30) Foreign Application Priority Data
Sep. 6, 2004 (JP) 2004-258910
Jan. 21, 2005 (JP) 2005-14412

(51) Int. Cl. H01L 21/00

(52) U.S. Cl. 438/64

(57) ABSTRACT

The present invention provides a method of manufacturing solid-state imaging devices comprising the steps of: forming a large number of solid-state image sensing devices over a wafer; forming, in positions matching said solid-state image sensing devices on the under face of a transparent flat plate to be joined to said wafer, frame-shaped spacers of a prescribed thickness each in a shape of surrounding an individual solid imaging element; aligning said wafer and said transparent flat plate opposite each other; supporting with a fixed table substantially the whole of one of the under face of said wafer and the upper face of said transparent flat plate, supporting substantially the other face with a pressing member via an elastic member, and thereby joining said wafer and said transparent flat plate via said spacers by the pressing member; and splitting said wafer and said transparent flat plate individual solid-state image sensing devices.

### BACKGROUND OF THE INVENTION

1. Field of the Invention

The present invention relates to a manufacturing method and a joining device for solid-state imaging devices, and more particularly to a manufacturing method and a joining device for solid-state imaging devices suitable for the manufacture of chip size package (CSP) type solid-state imaging devices.

2. Related Art

Today, even further size reductions are required of solid-state imaging devices, consisting of CCDs or CMOSs, for use in digital cameras and mobile telephones. For this reason, the main stream is now shifting from conventional large packages, in each of which a whole solid imaging element chip is sealed airtight into a package of ceramic or some other material to chip size packages (CSPs), each about as large as a solid imaging element chip itself.

In this context, there is proposed a method by which spacers are formed on a transparent glass plate correspondingly to positions of surrounding the light receiving portions of solid-state image sensing devices formed in a large number over a wafer (semiconductor substrate); this transparent glass plate is stuck to the wafer in the spacer portion to form a gap between it and the wafer, and the transparent glass plate and the wafer are diced along scribe lines to separate them into individual solid-state imaging devices (see Japanese Patent Application Laid Open No. 2002-231921 for instance).

FIG. 18 shows a perspective view of such a transparent glass plate 1 and wafer 2. As illustrated in this drawing, solid-state image sensing devices 3, 3 . . . and pads 4, 4, . . . each matching one or another of individual solid-state imaging devices are formed on the wafer 2. On the other hand, the layer of spacers 5 is formed on the under face of the transparent glass plate 1 as shown in FIG. 19.

### SUMMARY OF THE INVENTION

However, the art disclosed in Japanese Patent Application Laid Open No. 2002-231921 involves a problem that, when the transparent glass plate and the wafer are stuck together, uneven thicknesses of the transparent glass plate and the wafer might invite faulty joining. FIG. 20, illustrating this phenomenon, is an expanded sectional view of the essential part of a state in which the transparent glass plate 1 and the wafer 2 are stuck together. As shown in FIG. 20, a position of faulty adhesion between the layer of the spacers 5 and the wafer 2 is found where an arrow D points to.

In such a state, foreign matter would inevitably enter into a gap 6 through this portion of faulty adhesion. For instance, where dicing is performed with a dicing apparatus or the like, the dicing fluid will infiltrate into the gap 6 through this portion of faulty adhesion. FIG. 21, illustrating this phenomenon, is an expanded sectional view of the essential part of a state in which dicing is performed with the transparent glass plate 1 and the wafer 2 being stuck together. Unlike in FIG. 20, however, the wafer 2 is in a higher position and the glass plate 1 is positioned below it. Incidentally, what is stuck to the under face of the glass plate 1 is an adhesive film 1A, introduced to prevent the solid-state imaging devices after the dicing from scattering.

As illustrated in FIG. 21, a revolving dicing blade 7 cuts into the laminated object from the rear side of the wafer 2. To facilitate this dicing, dicing fluid (coolant) 9 is supplied to the peripheral edge of the dicing blade 7 through nozzles 8 and 8.

However, if there is any portion of faulty adhesion between the layer of the spacers 5 and the wafer 2 as referred to above, the dicing fluid 9 will infiltrate into the gap 6 to make it impossible to maintain acceptable standards of the products.

An object of the present invention, attempted in view of this circumstance, is to provide a manufacturing method and joining device for solid-state imaging devices which make possible prevention of faulty adhesion, which would give rise to rejectable products, in cutting or otherwise machining a laminated structure composed of a substrate (wafer) and a planar member (glass plate), which are joined together, such as a chip size package (CSP) type solid imaging device.

In order to achieve the objected state above, a method of manufacturing solid-state imaging devices according to the invention comprises the steps of forming a large number of solid-state image sensing devices over the upper face of a wafer; forming, in positions matching the solid-state image sensing devices on the under face of a transparent flat plate to be joined to the wafer, frame-shaped spacers of a prescribed thickness each in a shape of surrounding an individual solid imaging element; aligning the wafer and the transparent flat plate opposite each other; a step of supporting with a fixed table substantially the whole of one of the under face of the wafer and the upper face of the transparent flat plate that have been aligned, supporting substantially the whole of the other face with a pressing member via an elastic member, and thereby joining the wafer and the transparent flat plate via the spacers by applying a pressure with the pressing member; and splitting the wafer and the transparent flat plate that have been joined into individual solid-state image sensing devices.

According to the invention, at the step of joining the wafer and the transparent flat plate via the spacers, substantially the whole of one of the under face of the wafer and the upper face of the transparent flat plate is supported with a fixed table, and substantially the whole of the other face with the pressing member via the elastic member. Therefore, this buffering member absorbs any thickness fluctuations of the transparent glass plate and of the wafer, allowing no trouble, which would give rise to faulty adhesion, to occur and thereby keeping the quality of products satisfactory.

According to the invention, it is preferable for the ASKER C hardness as set forth in The Society of Rubber Industry, Japan Standard (SRIS) of the elastic member to be 20 to 40. Such an elastic member absorbs any thickness fluctuations of the transparent glass plate and of the wafer, allowing no trouble, which would give rise to faulty adhesion, to occur and thereby keeping the quality of products satisfactory.

According to the invention, it is preferable for a pressing force by a fluid pressure to be applied from the rear face of the pressing member. Such a pressing system makes it easier for the pressing face of the pressing member to become parallel to the wafer or the transparent flat plate, and enables the advantages of the invention to be exerted even more effectively.

According to the invention, the pressing member may be engaged with a pressure vessel on the rear side of the pressing member via a sealing member disposed on the peripheral edge of the pressing member, pressure fluid being fed between the pressure vessel and the pressing member; and it is preferable, at the joining step, for the pressing member to be able to incline pivoting on substantially the center point of the other one of the under face of the wafer and the upper face of the transparent flat plate.

Such a pressing system makes it easier for the pressing face of the pressing member to become parallel to the wafer or the transparent flat plate, and prevents any force in the horizontal direction which could invite a slip between the wafer and the transparent flat plate from occurring, thereby enabling the advantages of the invention to be exerted even more effectively.

Thus, where a system of pressing by fluid pressure is used and the pressing member can be inclined, if the center of revolution of the pressing member is away from the pressing face, a force in the horizontal direction which could invite a slip between the wafer and the transparent flat plate will occur when the pressing member is inclined, and this may lead to inaccuracy of alignment.

Unlike this, the center of revolution of the pressing member is on the pressing face in the configuration according to the invention, the trouble of slip between the wafer and the transparent flat plate cannot occur. Therefore, solid-state imaging devices can be manufactured with a high level of aligning accuracy.

Incidentally, in the context of this specification, “solid-state image sensing devices” refer to a set of many solid-state image sensing devices (CCDs or the like) in a two-dimensional array, and one set in an array form corresponds to one set of solid-state imaging devices.

According to the invention, there is also provided a joining device for joining two planar members aligned opposite each other by applying pressure, comprising a fixed table supporting substantially the whole of one of the planar members; a pressing member supporting substantially the whole of the other of the planar members; a pressure vessel which is disposed on the rear side of the pressing member and supports the pressing member via a sealing member disposed on the peripheral edge of the pressing member; a pressing force supplying device which feeds pressure fluid between the pressure vessel and the pressing member and applies a pressing force to the two planar members by way of the fixed table and the pressing member; and a pressing member supporting device which supports the pressing member to enable the member to incline pivoting on substantially the center point of the surface of the other one of the planar members.

The joining device according to the invention is applicable not only to the manufacture of the solid-state image sensing devices but also extensively to joining two planar members in general. As described above, there will occur no trouble of the two planar members slipping off each other, because the pressing member pivots on the pressing face. Therefore, it enables two planar members to be joined with a high level of aligning accuracy.

As described so far, the solid imaging device manufacturing method according to the invention enables the wafer and the transparent flat plate to be joined together with the spacer in-between without allowing any trouble, which would give rise to faulty adhesion, to occur and thereby the quality of products to be kept satisfactory.

### BRIEF DESCRIPTION OF THE DRAWINGS

FIG. 1 is a perspective view of a solid imaging device fabricated by the solid imaging device manufacturing method according to the present invention;

FIG. 2 shows a sectional view of the essential part of the solid imaging device fabricated by the solid imaging device manufacturing method according to the invention;

FIG. 3 is a flow chart showing the manufacturing process of the solid imaging device;

FIG. 4 is a perspective view of the transparent glass plate and the wafer;

FIG. 5 shows a sectional view of the transparent glass plate together with the spacer layer;

FIG. 6 shows a sectional view of the transparent glass plate together with the adhesive layer;

FIG. 7 is a flow chart showing details of a second phase of the manufacturing process;

FIG. 8 illustrates a method of applying the adhesive to a transfer film;

FIG. 9 illustrates a method of transferring the adhesive to the spacer;

FIG. 10 illustrates a method of peeling the transfer film off the spacer;

FIG. 11 is a perspective view of the position of applying a fixing adhesive to the wafer;

FIGS. 12A and 12B show sectional views of the essential part of a state in which the transparent glass plate and the wafer are tentatively stuck together;

FIGS. 13A and 13B show sectional views of a device for sticking the transparent glass plate and the wafer together;

FIGS. 14A and 14B show sectional views of the essential part of a process of sticking the transparent glass plate and the wafer together under pressure;

FIG. 15 shows a sectional view of the essential part of a state in which the transparent glass plate and the wafer are diced;

FIG. 16 is a perspective view of a solid imaging device fabricated by another mode of the solid imaging device manufacturing method according to the invention;

FIG. 17 shows a sectional view of the essential part of the solid imaging device fabricated by the other mode of the solid imaging device manufacturing method;

FIG. 18 shows a perspective view of such a transparent glass plate and wafer according to the related art;

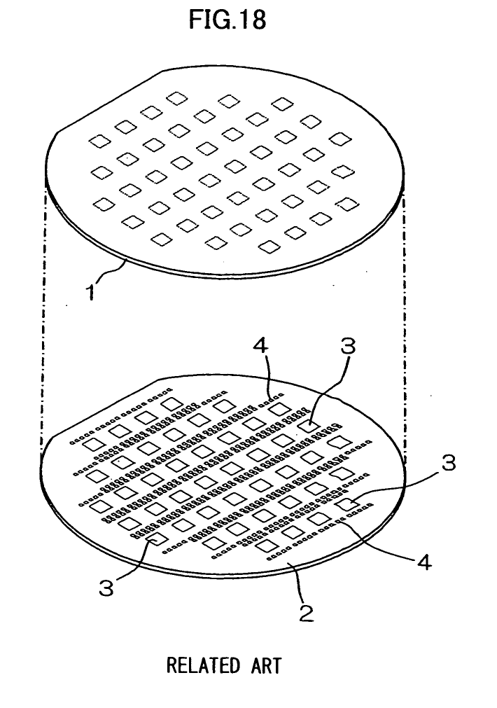

FIG. 19 shows a plan of a spacer layer on the under face of the transparent glass plate according to the related art;

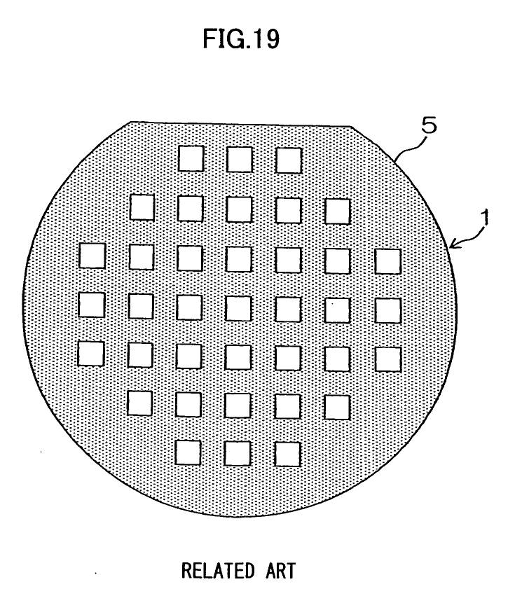

FIG. 20 is a sectional view of the essential part of a state in which the transparent glass plate and the wafer are stuck together according to the related art; and

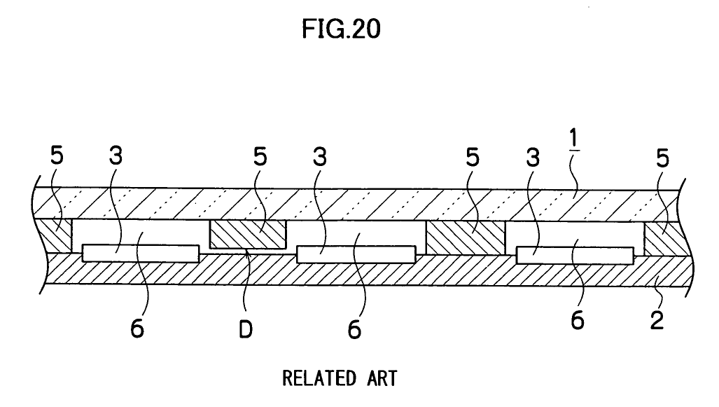

FIG. 21 shows a sectional view of the essential part of a state in which the transparent glass plate and the wafer are diced according to the related art.

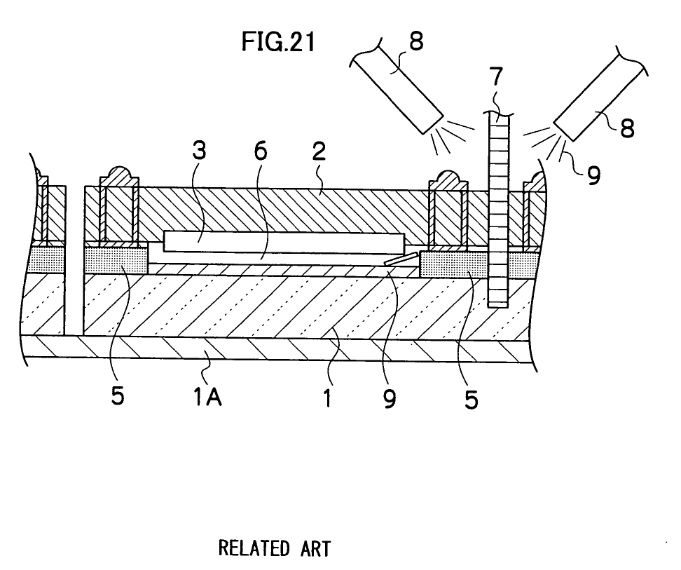

### DETAILED DESCRIPTION OF THE PREFERRED EMBODIMENTS

A preferred embodiment of the solid imaging device manufacturing method according to the present invention will be described in detail below with reference to accompanying drawings. In these drawings, the same members are designated by respectively the same reference numbers or characters.

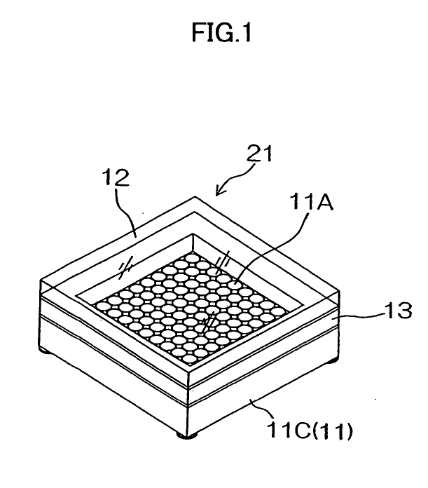

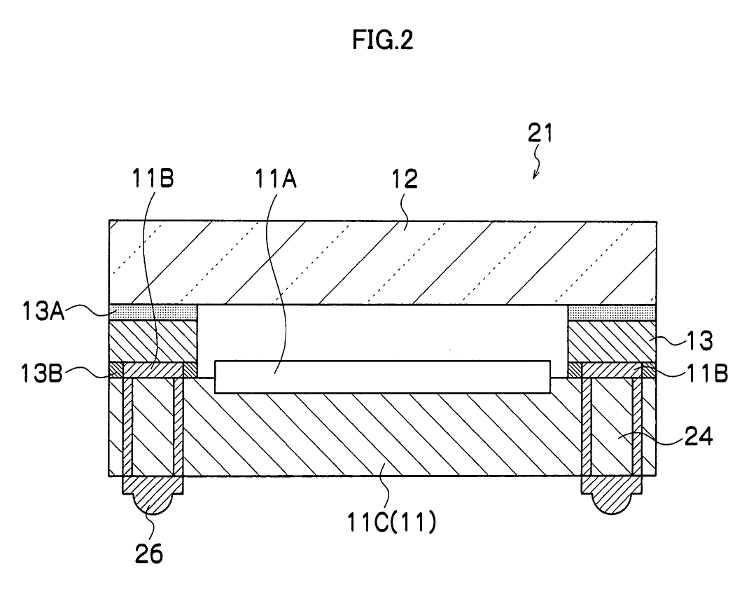

FIG. 1 and FIG. 2 show a perspective view of the external shape and a sectional view of the essential part, respectively, of a chip size package (CSP) type solid imaging device fabricated by a solid imaging device manufacturing method according to the invention.

A solid imaging device 21 comprises a solid imaging element 11A; a rectangular solid imaging element 11C provided with pads 11B, 11B . . . , which are a plurality of connection terminals to be electrically connected to the solid imaging element 11A; frame-shaped spacers 13 so fitted over the solid imaging element chip 11C as to surround the solid imaging element 11A; and a transparent glass plate 12 fitted over these spacers 13 to seal the solid imaging element 11A.

Incidentally, the solid imaging element chip 11C results from splitting of a semiconductor substrate (wafer) 11 (corresponding to a substrate in the invention) to be described afterwards. The spacers 13 are joined to the transparent glass plate 12 via an adhesive 13A and to the wafer 11 via an adhesive 13B.

A usual semiconductor manufacturing process is applied to the fabrication of the solid imaging element 11A. The solid imaging element 11A comprises a photodiode which is a light receiving element formed on the wafer 11; a transfer electrode for externally transferring an excitation voltage; a light shield film having an aperture; an inter-layer insulation film; an inner lens formed over the inter-layer insulation film; a color filter disposed over the inner lens with an intermediate layer between them; and a micro-lens disposed over the inner lens with an intermediate layer between them among other elements.

As the solid imaging element 11A is configured in this way, incident lights from outside are condensed by the micro-lens and the inner lens and irradiate the photodiode to raise the effective aperture rate.

The pads 11B, 11B . . . are formed of, for instance, an electroconductive material by printing over the solid imaging element chip 11C. Wiring is also laid by printing between the pads 11B and the solid imaging element 11A.

Further, through-wiring 24 penetrating the solid imaging element chip 11C is provided to establish conduction between the pads 11 B and an external connection terminal 26.

A single crystal silicon wafer would be generally used as the wafer 11.

The spacers 13 are formed of an inorganic material, for instance silicon. It is preferable for the material of the spacers 13 to be similar in physical properties, including the coefficient of thermal expansion, to the wafer 11 and the transparent glass plate 12. For this reason, silicon is the most suitable material for the spacers 13.

In order to prevent the photodiode of the CCD from being destroyed, transparent α-ray shielding glass is used for the transparent glass plate 12.

Next will be outlined the manufacturing process of the CSP type solid imaging device to which the solid imaging device manufacturing method according to the invention is to be applied.

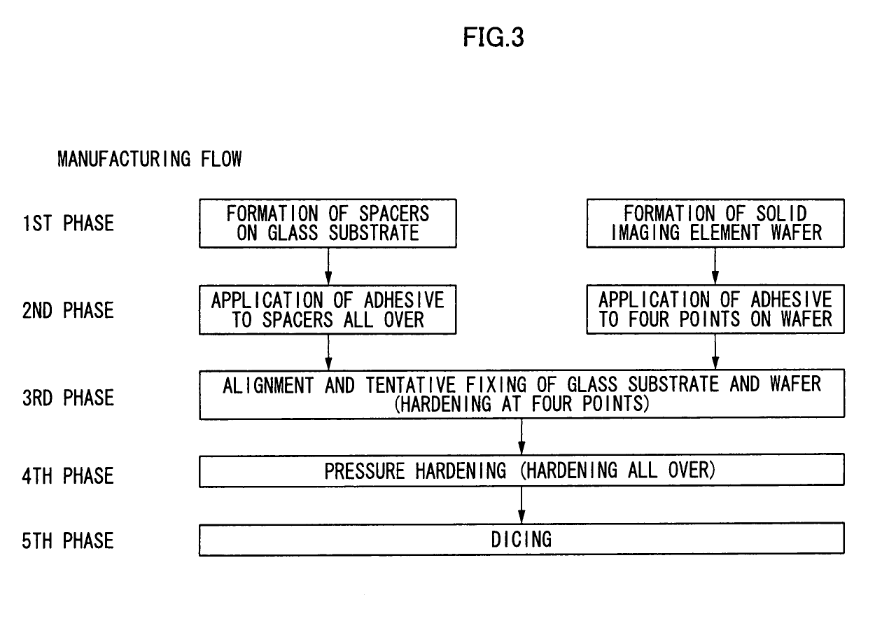

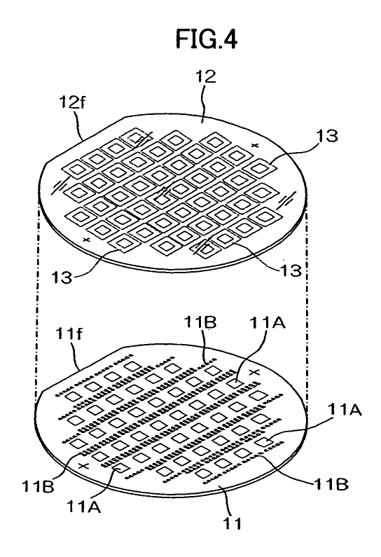

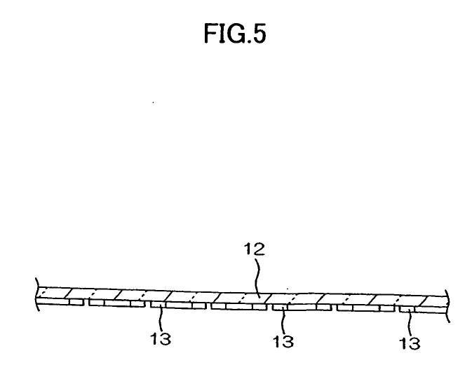

FIG. 3 is a flow chart showing the manufacturing process of the solid imaging device. In a first phase of the process, many spacers 13 are formed over the transparent glass plate 12 and the solid-state image sensing devices 11A, 11A . . . and the pads 11B, 11B . . . are so formed over the wafer 11 as to match the individual solid imaging device 21 as shown in FIG. 4 and FIG. 5.

Thus, FIG. 4 shows a perspective view of the transparent glass plate 12 and the wafer 11, and FIG. 5 shows a sectional view of the transparent glass plate 12 together with the layer of the spacers 13.

The size of the glass plate 12 and the wafer 11 may be about 102 mm (4 inches) in external diameter for instance, though it depends on the chip size of the solid imaging device 21 (usually 3 to 35 mm square). The thickness of the glass plate 12 may be 0.3 to 0.7 mm for instance, and the thickness of the wafer 11 may be 0.3 to 0.7 mm for instance.

Incidentally, as shown in FIG. 4, alignment marks are formed within the circles of the transparent glass plate 12 and the wafer 11 on their two sides each.

The thickness of the spacers 13 may be 0.02 to 0.2 mm for instance. These spacers 13 are formed by, for example, the following method. First, an inorganic material film is formed by stacking an inorganic material, such as silicone, over the transparent glass plate 12 by applying a spin coat or using a CVD device. Then the pattern of many spacers 13 is formed from the inorganic material film by photolithography and etching or otherwise.

Where photolithography and etching are to be applied, first an inorganic material film is formed all over the surface of the glass plate 12; then a photoresist layer is formed by photolithography on the parts of the surface matching the spacers 13 in FIG. 4; and the pattern of the spacers 13 is formed by etching.

Alternatives to spin coating include adhering the transparent glass plate 12 and a silicon wafer to each other in order to form an inorganic material film over the transparent glass plate 12. Another alternative is to form the spacers 13 directly over the transparent glass plate 12 by printing with an inorganic material.

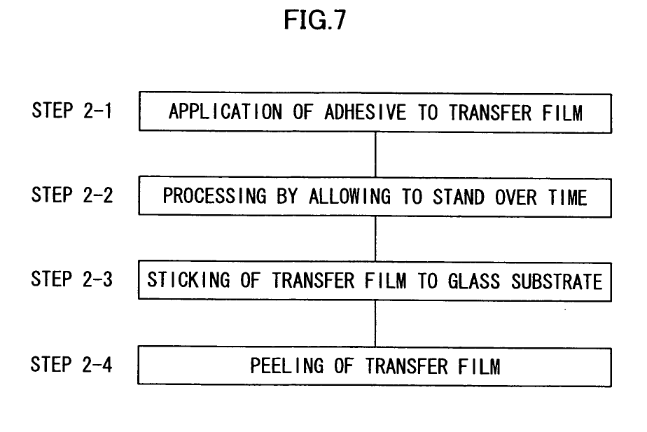

Further, where the spacers 13 are to be joined onto the transparent glass plate 12 via the adhesive 13A as already described with reference to FIG. 2, this adhesive 13A can be applied onto the transparent glass plate 12 in the same way as the application of the adhesive 13B onto the spacers 13 to be described afterwards with reference to FIG. 7.

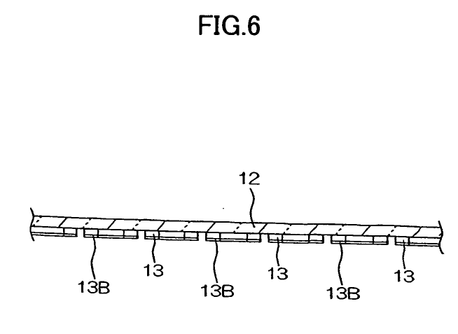

In the second phase of the manufacturing process, the adhesive 13B is applied thinly and uniformly over the upper face of each spacer 13 on the transparent glass plate 12 as shown in FIG. 6. Regarding the choice of the type of material for the adhesive 13B, a cold-setting resin adhesive of, for instance, an epoxy or silicon material, is used with a view to prevention of warping and infiltration of moisture or the like at the time of hardening and thereby ensuring high reliability. Also, an adhesive 13B of about 0.1 to 10 Pa-s in viscosity is used to achieve a film thickness of approximately 5 to 10 μm.

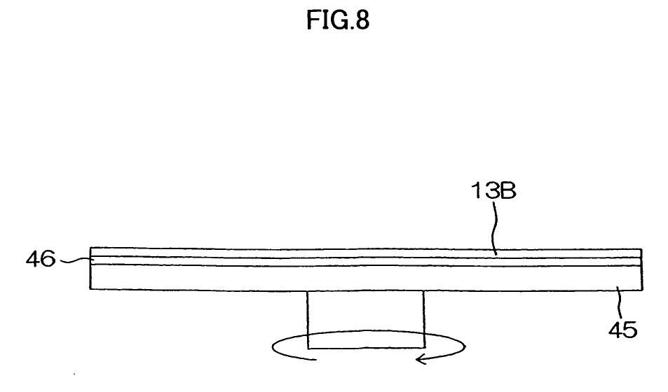

The adhesive 13B is applied to the spacers 13, for example, at steps 2-1 through 2-4 shown in the flow chart of FIG. 7 and FIG. 8 through FIG. 10. At step 2-1, a transfer film 46 is mounted on a highly flat spinner table 45 as shown in FIG. 8. This transfer film 46 is sucked onto and held on the spinner table 45 by air suction or otherwise so that it may not slip out of place or become creased.

The transfer film 46 is a thin polyethylene telephthalate (PET) film formed flat, and is larger in external size than the transparent glass plate 12. The adhesive 13B, after it is supplied in a prescribed quantity, is applied onto the transfer film 46 mounted on the spinner table 45 uniformly in a thickness of 6 to 10 μm, preferably 8 μm, by high speed revolution of the spinner table 45.

Incidentally, a blade coater, bar coater or the like may as well be used for applying the adhesive 13B onto the transfer film 46.

Generally, cold-setting adhesives for optical use are known to be poor in wettability vis-à-vis an inorganic material, such as silicon, which constitutes the spacers 13, but they are also known to be improved in wettability by increasing their viscosity. However, a highly viscous adhesive makes it more difficult to control the thickness of its application.

In view of this problem, this embodiment involves step 2-2, at which the adhesive 13B is allowed to stand for a prescribed length of time after its application to the transfer film 46 so that the viscosity of the adhesive 13B be increased over time. This processing over time requires such adjustment of temperature and time as the viscosity of the adhesive 13B reach 9.5 to 10 Pa·s (9500 to 10000 cps) approximately.

Since the viscosity of the adhesive 13B is caused in this way to vary over time, the adhesive 13B of a lower viscosity at the time its application to the transfer film 46 can be used to make possible accurate control of its coat thickness.

To add, where a hydrophilic adhesive is used, it is possible to irradiate the spacers 13 with plasma or ultraviolet rays to achieve surface reforming. The wettability of the adhesive vis-à-vis the silicon spacers can be thereby improved.

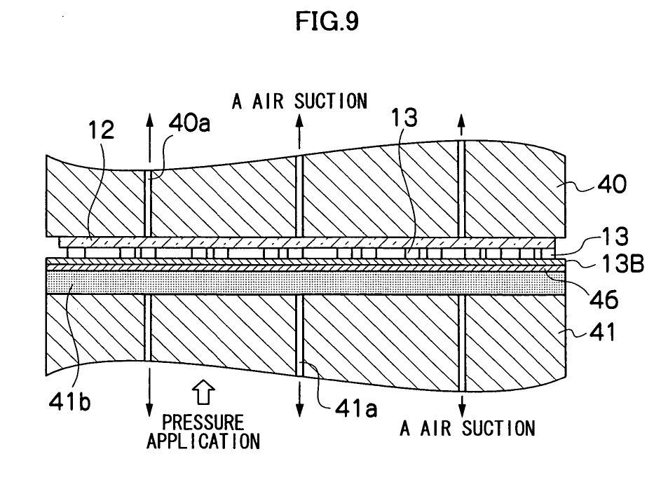

At step 2-3, the transparent glass plate 12 and the transfer film 46 are stuck to each other by using an aligning device or manually. For instance, as shown in FIG. 9, the aligning device comprises a glass holding table 40 for suction-holding the transparent glass plate 12 by sucking air through suction holes 40a and a film holding table 41 which is arranged underneath this glass holding table 40 and suction-holds the transfer film 46 via a sponge 41b by sucking air through suction holes 41a. The film holding table 41 is enabled to shift vertically like a known Z-axis shifting table.

The film holding table 41 rises in a state in which the transfer film 46 coated with the adhesive 13B is mounted on the sponge 41b, and presses the transfer film 46 against the large number of spacers 13 on the transparent glass plate 12 with uniform force.

The sponge 41b should have such a degree of hardness as will not damage the spacers 13 and yet can firmly press the transfer film 46 against the spacers 13. This ensures that the adhesive 13B over the transfer film 46 be kept in secure contact with the spacers 13 and that the transparent glass plate 12 and the transfer film 46 be adhered to each other.

The transparent glass plate 12 and the transfer film 46 may as well be stuck to each other by moving a press roller over the transparent glass plate 12.

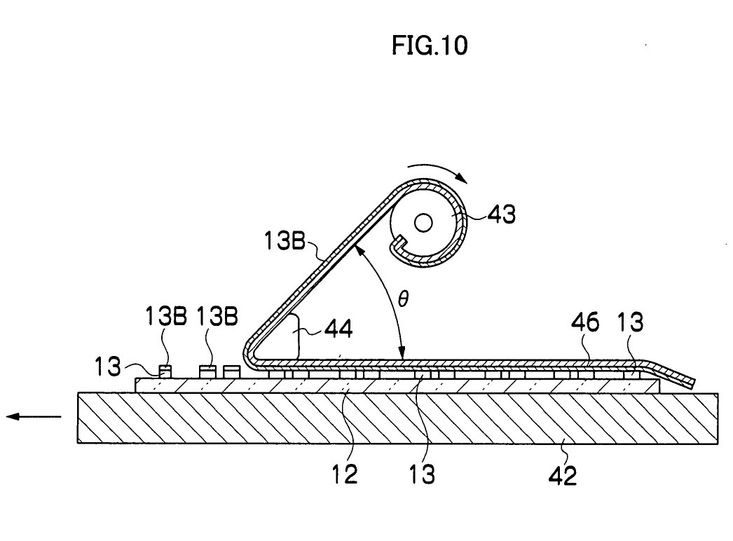

At step 2-4, as shown in FIG. 10, the transfer film 46 is peeled off the transparent glass plate 12, and the adhesive 13B is transferred onto the spacers 13.

The film peeling device used at this step comprises a work table 42 for suction-holding the mounted transparent glass plate 12 by air suction or otherwise, a take-up roller 43 with which one end of the transfer film 46 is engaged, and a peeling guide 44 which is in contact with the upper face of the transfer film 46 and keeps constant the angle θ formed by the transfer film 46 being peeled and the transparent glass plate 12.

The work table 42 is made slidable in right-and-left directions in the drawing by a table shifting mechanism used for an XY table for instance.

The film peeling device, upon sliding to the left (in the drawing) of the work table 42, starts take-up of the transfer film 46 by the take-up roller 43, and peels the transfer film 46 off, successively from one end of the transparent glass plate 12.

As the rear face of the transfer film 46 is restricted by the peeling guide 44 in that process, the angle θ formed by the transparent glass plate 12 and the transfer film 46 is kept constant all the time, and the adhesive 13B of a fixed thickness is transferred onto each of the spacers 13 of the transparent glass plate 12.

To add, if the size of the transfer film 46 is too large to be engaged with the take-up roller 43, an extension film can be stuck to the end of the transfer film 46.

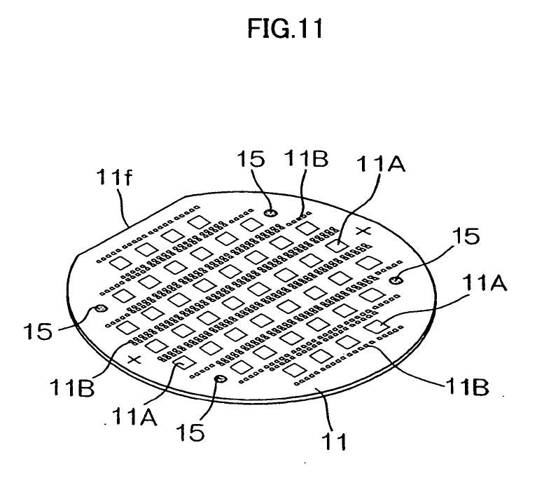

Referring back to the flow chart of FIG. 3, the second phase of the manufacturing process of the wafer 11 will be described. In this phase, as shown in FIG. 11, a fixing adhesive 15 is applied to four positions of the wafer 11 in dots. Preferable materials for this fixing adhesive 15 include a radiation-setting type adhesive (for instance an ultraviolet ray-setting adhesive).

Thus, this fixing adhesive 15 is required to have a property of not hardening for many hours if left intact after its application and of instantaneously hardening when irradiated with a radiation (for instance ultraviolet rays).

The dose of the fixing adhesive 15 in each position should be sufficient for the fixing adhesive 15 to remain in contact with the transparent glass plate 12 when the transparent glass plate 12 is aligned in the next (third) phase of the process over the wafer 11 and brought into tight contact with it.

Further, it is preferable for each dot of the fixing adhesive 15 to be small enough not to spread excessively in that process. Otherwise, the dots of the fixing adhesive 15 would expand so much as to cover the spacers 13, the solid imaging element 11A and the pads 11B to make the product defective in quality.

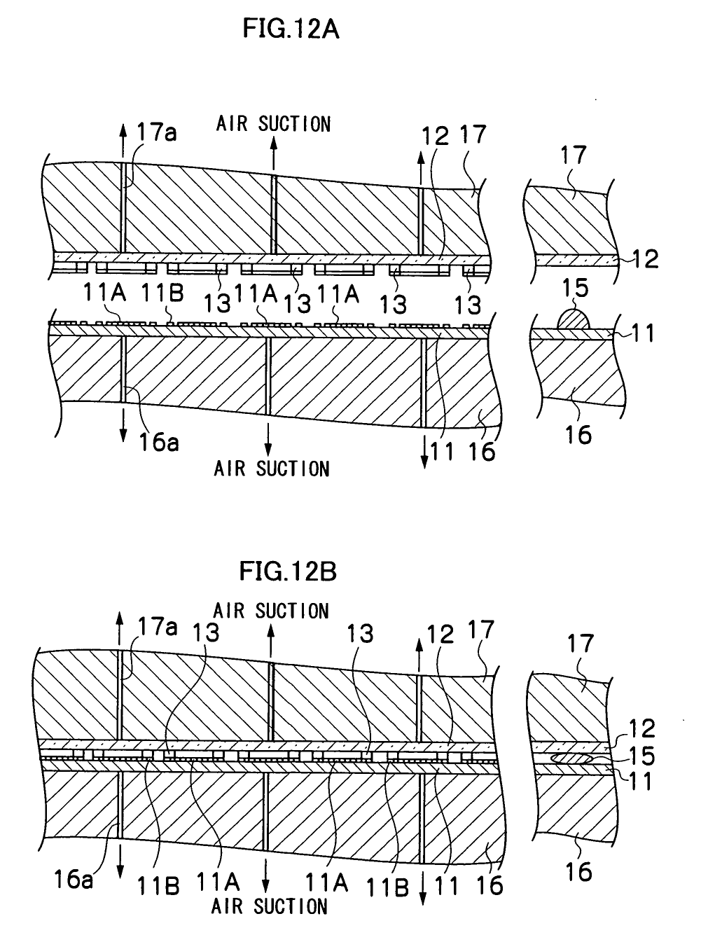

In the third phase of the manufacturing process, as shown in FIG. 12(B), the transparent glass plate 12 is aligned over the wafer 11 on which many solid-state image sensing devices 11A and pads 11B are formed, and then tentatively fixed. An aligning/sticking device is used for aligning and tentatively fixing the transparent glass plate 12 and the wafer 11.

As shown in FIG. 12(A), the aligning/sticking device comprises a sticking table 16 which sucks air through air suction holes 16a and positions and holds the wafer 11 and a positioning table 17 which similarly sucks air through air suction holes 17a, holds the transparent glass plate 12 and adjusts the position of the transparent glass plate 12 in the XY direction and the θ direction (revolving direction) to match the wafer 11.

With this the positioning table 17, the relative positions of the wafer 11 and the transparent glass plate 12 are adjusted by utilizing orientation flats 11f and 12f (see FIG. 4) of the wafer 11 and the transparent glass plate 12, respectively, and the aforementioned alignment marks are provided as appropriate.

To add, it is preferable for at least the part of this positioning table 17 matching the fixing adhesive 15 to be transparent or translucent (or in a notched state).

After that, by bringing down the positioning table 17 to place the transparent glass plate 12 over the wafer 11 and uniformly pressing the transparent glass plate 12 with the positioning table 17, the transparent glass plate 12 and the wafer 11 are stuck to each other. In this process, the fixing adhesive 15 comes into contact with the transparent glass plate 12 as described above.

Then, the fixing adhesive 15 is irradiated with ultraviolet rays from the rear face (upper face) of the positioning table 17 by having the transparent or translucent part of the positioning table 17 and the transparent glass plate 12, and the fixing adhesive 15 is thereby hardened. This causes, though the adhesive 13B is not yet hardened, the fixing adhesive 15 to fix the transparent glass plate 12 over the wafer 11 not to shift relative to each other in the horizontal direction (temporarily pasted).

Incidentally, the reason for the absence of the sponge 41b, which is used in the aligning device shown in FIG. 9, in the aligning/sticking device for sticking the transparent glass plate 12 and the wafer 11 to each other is the need for highly accurate position adjustment between the solid-state image sensing devices 10A and the spacers 13 in sticking the transparent glass plate 12 and the wafer 11 together.

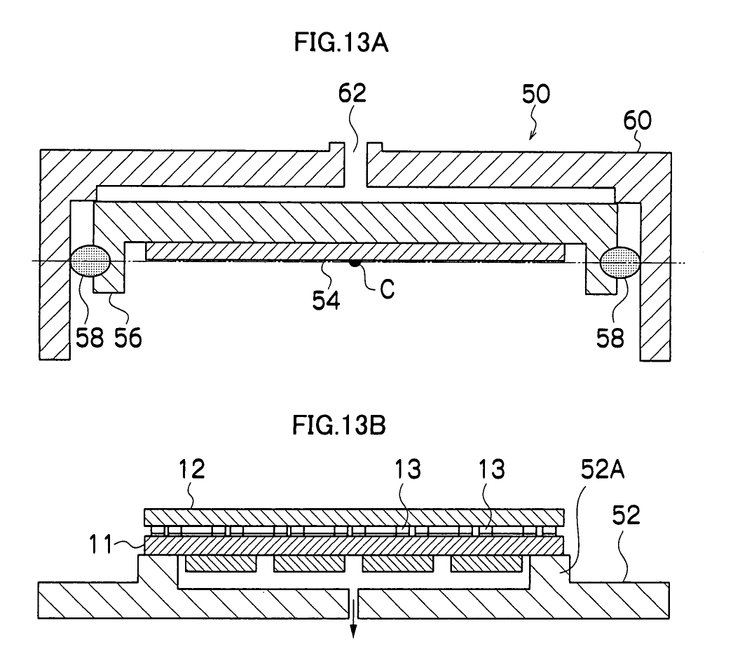

In the fourth phase of the manufacturing process, the transparent glass plate 12 and the wafer 11 tentatively stuck to each other with the aligning/sticking device of FIGS. 12 are removed from this aligning/sticking device, transferred to a pressure sticking device 50 shown in FIGS. 13, and securely stuck together not to allow peeling off.

In FIGS. 13, 13(A) is a sectional view showing the configuration of a pressure vessel 60 and other elements, and 13(B), a sectional view showing the configuration of a supporting table 52 and other elements.

The pressure sticking device 50 comprises the supporting table 52 (fixed table) on which a laminated object consisting of the tentatively stuck transparent glass plate 12 and wafer 11 is mounted, a pressing plate 56 (pressing member) which is arranged above this supporting table 52 and presses the whole transparent glass plate 12 with a uniform force via a buffering member 54, and the pressure vessel 60 which is arranged above the pressing plate 56 and engaged with the pressing plate 56 via an O ring 58 (sealing member) disposed on the peripheral edge of the pressing plate 56.

The supporting table 52 is a table-shaped member fixed to a base (body) (not shown). Its work mounting part 52A on the upper side is formed in substantially the same size as the transparent glass plate 12 and the wafer 11. It is preferable for the work mounting part 52A to be machined flat and smooth so that, when it supports the transparent glass plate 12 or the wafer 11, the transparent glass plate 12 or the wafer 11 may not be deformed.

A plurality of vacuum suction holes are formed in substantially the whole surface of this work mounting part 52A, and can fix the transparent glass plate 12 or the wafer 11 in tight contact by reducing the pressure as indicated by an arrow in FIG. 13(B).

The pressing plate 56 is a shallow circular measuring cup-shaped member whose inner circumferential size is slightly greater than the outer circumferential size of the transparent glass plate 12 and the wafer 11, and is so supported as to direct its opening downward. The buffering member 54 is fixed to the bottom of the circular measuring cup of the pressing plate 56 (the under face in FIG. 13).

For the buffering member 54, a member of 20 to 40 in ASKER C hardness is used. The choice of materials for the buffering member 54 includes various high molecular materials, of which silicon sponge, for instance, can be preferably used. The preferable thickness range of the buffering member 54 is from 1 to 3 mm.

A groove in which the O ring 58 can be fixed is formed all around the outer peripheral edge of the pressing plate 56, and the O ring 58 is snapped into this groove.

The pressure vessel 60 is a shallow circular measuring cup-shaped member whose inner circumferential size is slightly greater than the outer circumferential size of the pressing plate 56, and is so supported as to direct its opening downward. This pressure vessel 60 is supported by a base (body) (not shown) to be vertically shiftable via an elevating mechanism (not shown).

It has to be noted, however, that the pressure vessel 60 is so structured as to be able only to shift vertically but unable to oscillate (incline) in a so-called swinging motion, because it is subject to the reaction force which arises when the pressing plate 56 is pressed via a pressure fluid and this reaction force is considerably great.

The pressure vessel 60 is formed to be slightly smaller in internal diameter than the external diameter of the O ring 58 in the state of being fixed in the groove in the outer peripheral edge of the pressing plate 56. Therefore, the pressing plate 56 engages with the pressure vessel 60 via the O ring 58. The pressing plate 56 is disposed to be able to vertically shift within the pressure vessel 60.

Further, the pressing plate 56 is enabled to oscillate (incline) in a so-called swinging motion to some extent within the pressure vessel 60. The center of this oscillating motion falls on the intersection between the center of the pressing plate 56 in the planar direction and that of the O ring 58 in the vertical direction (point C in FIG. 13(A)).

A through hole 62 for feeding the pressure fluid is formed at the center of the bottom face (the upper face in FIG. 13) of the pressure vessel 60 so that the pressure fluid be fed between the pressure vessel 60 and the pressing plate 56. In this process, the action of the O ring 58 prevents the pressure fluid fed between the pressure vessel 60 and the pressing plate 56 from leaking out.

This pressure fluid may be either gas (e.g. air) or liquid (e.g. water). In this embodiment, compressed air supplied from an air compressor (not shown) is used.

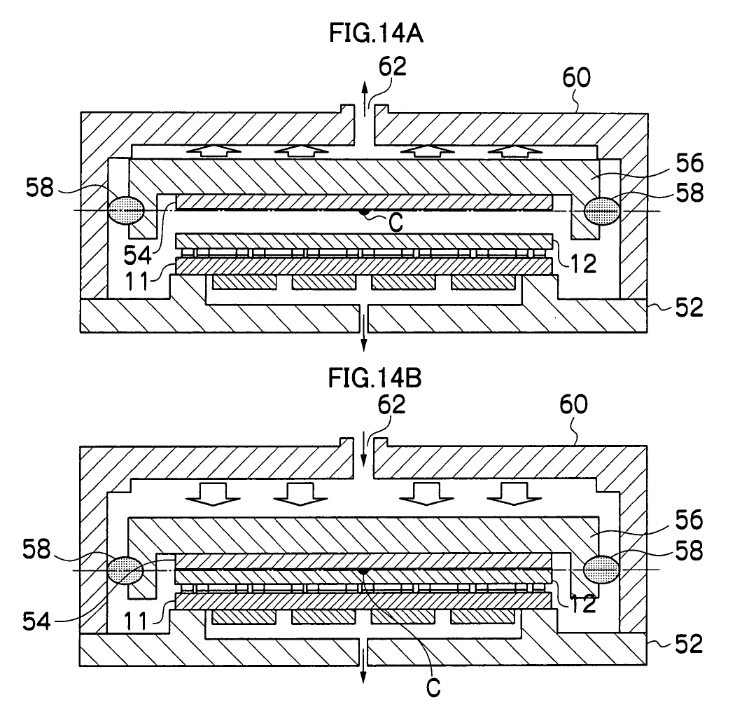

Next will be described the sticking procedure using the pressure sticking device 50. FIGS. 14 show sectional views of the essential part of the process of sticking the transparent glass plate 12 and the wafer 11 together under pressure.

First, as shown in FIG. 13(B) earlier referred to, the wafer 11 is fixed to the surface of the work mounting part 52A in tight contact by reducing the pressure in the supporting table 52 as indicated by arrows in the drawing.

Then, as shown in FIG. 14(A), the pressure vessel 60 (together with the pressing plate 56) is brought down, and set above the supporting table 52. In this process, the pressing plate 56 is in a process of being lifted by reducing the pressure within the pressure vessel 60 as indicated by arrows in the drawing, and the under face of the buffering member 54 and the upper face of the transparent glass plate 12 are at a prescribed distance from each other.

Next, as shown in FIG. 14(B), the inside of the pressure vessel 60 is pressured as indicated by the arrows. This brings down the pressing plate 56, which presses the whole transparent glass plate 12 via the buffering member 54. Incidentally, when the pressing plate 56 descends, the air staying underneath the pressing plate 56 and the O ring 58 is discharged outside as indicated by broken arrows.

Pressing of the transparent glass plate 12 and the wafer 11 by this pressure sticking device 50 is continued for a prescribed length of time required for the hardening of the adhesive 13B. Thus in the fourth phase of the manufacturing process, final sticking is carried out by continuing the application of pressure. The pressed wafer 11 and transparent glass plate 12 are slightly deformed by their thickness fluctuations and warping, and the state of contact between the spacer 13 and the wafer 11 becomes uniform.

Further, if the thickness of the laminated object of the wafer 11 and the transparent glass plate 12 varies in a wedge form, it will be preferable for the pressing plate 56 (the buffering member 54) also to incline and follow this shape, and it can follow this shape because the pressing plate 56 can incline pivoting on point C in FIG. 13 as described above.

Thus since point C coincides with the center point of the upper face of the transparent glass plate 12, which is the pressed face, in FIG. 14(B), the aforementioned shape can be followed. Also, as the center of revolution of the pressing plate 56 is on the pressing face, there can be no trouble of the wafer 11 and the transparent glass plate 12 deviating from each other. Therefore, the solid-state imaging devices 21 can be manufactured with a high level of aligning accuracy.

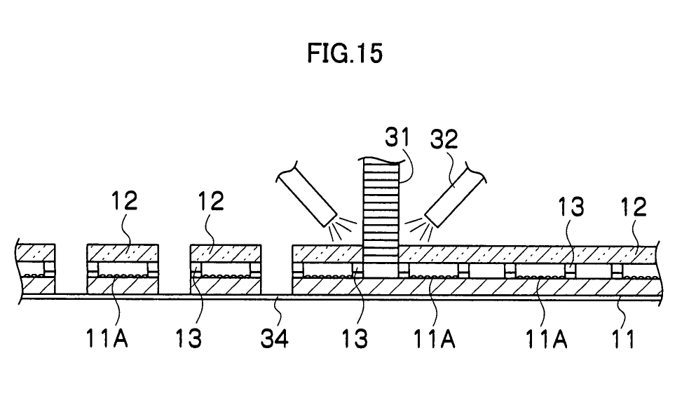

In the fifth phase of the manufacturing process, as shown in FIG. 15, the transparent glass plate 12 and the wafer 11 are diced, and many solid-state imaging devices 21 are formed. This dicing is accomplished with a diamond wheel 31 (grinding wheel) while spraying dicing fluid (coolant) from spray nozzles 32 to prevent the transparent glass plate 12 and the wafer 11 from being heating more than necessary. During this dicing procedure, no dicing fluid will infiltrate between the spacers 13 because the space between the spacers 13 and the wafer 11 is securely sealed by the adhesive 13B.

To add, a dicing tape 34 is stuck to the under face of the wafer 11 before performing the dicing to prevent the solid-state imaging devices 21 from scattering after the dicing.

As hitherto described, any solid imaging device manufacturing method according to the present invention, when the wafer 11 and the transparent glass plate 12 (transparent flat plate) are joined via the spacers 13, no trouble of faulty joining will occur, and the quality of the products can be thereby maintained at a satisfactory level.

Although the solid imaging device manufacturing method according to the invention has been described with reference to a preferred embodiment thereof, the invention is not limited to this embodiment, but can be implemented in various other modes.

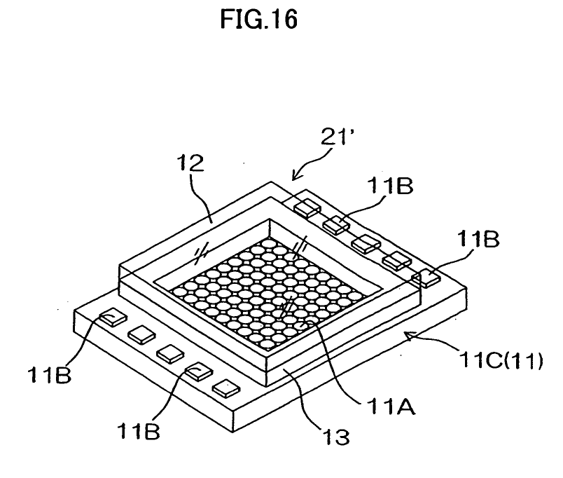

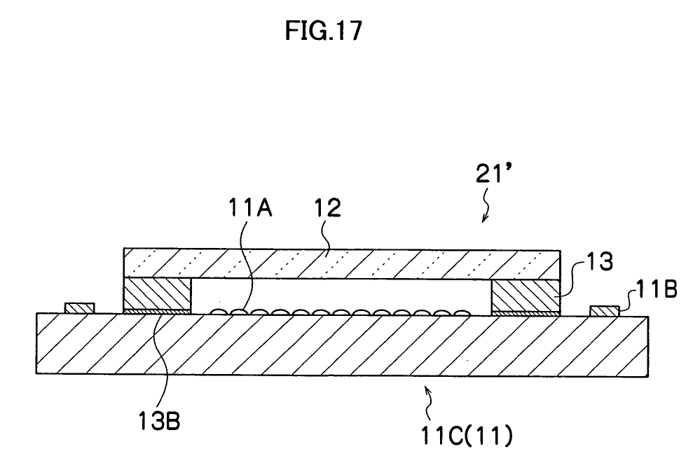

For instance, though the foregoing embodiment was described with reference to square and planar solid-state imaging devices 21 as shown in FIG. 1 and FIG. 2, it can be suitably applied to oblong rectangular and planar solid-state imaging devices 21′ as shown in FIG. 16 (perspective view) and FIG. 17 (sectional view), and similar effects can be expected. In the configuration of these solid-state imaging devices 21′, the end face of the solid imaging element chip 11C is not in line with the spacers 13 and the transparent glass plate 12 but protrudes, and pads 11B, 11B . . . are exposed on the surface of the solid imaging element chip 11C.

Further, though the pressing plate 56 is engaged with the pressure vessel 60 via the O ring 58 and enabled to oscillate (incline) in this embodiment, a similar function can as well be achieved in a different configuration.

For instance, a configuration in which the pressing plate 56 is linked with the pressing plate 56 via a plurality of linking mechanisms can provide the same effect.

In this case, the sealing of the pressing plate 56 and the pressure vessel 60 can be accomplished without using the O ring 58, for instance via bellows or a diaphragm.

What is claimed is:

1. A method of manufacturing solid-state imaging devices comprising the steps of:
forming a large number of solid-state image sensing devices over the upper face of a wafer;
forming, in positions matching said solid-state image sensing devices on the under face of a transparent flat plate to be joined to said wafer, frame-shaped spacers of a prescribed thickness each in a shape of surrounding an individual solid imaging element;
aligning said wafer and said transparent flat plate opposite each other;
supporting with a fixed table substantially the whole of one of the under face of said wafer and the upper face of said transparent flat plate that have been aligned, supporting substantially the whole of the other face with a pressing member via an elastic member, and thereby joining said wafer and said transparent flat plate via said spacers by applying a pressure with the pressing member; and
splitting said wafer and said transparent flat plate that have been joined into individual solid-state image sensing devices.

2. The method of manufacturing solid-state imaging devices according to claim 1, wherein the ASKER C hardness of said elastic member is 20 to 40.

3. The method of manufacturing solid-state imaging devices according to claim 1, wherein a pressing force by a fluid pressure is applied from the rear face of said pressing member.

4. The method of manufacturing solid-state imaging devices according to claim 2, wherein a pressing force by a fluid pressure is applied from the rear face of said pressing member.

5. The method of manufacturing solid-state imaging devices according to claim 1, wherein said pressing member is engaged with a pressure vessel on the rear side of the pressing member via a sealing member disposed on the peripheral edge of the pressing member, pressure fluid is fed between the pressure vessel and said pressing member; and
at said joining step, said pressing member can incline pivoting on substantially the center point of said other one of the under face of said wafer and the upper face of said transparent flat plate.

6. The method of manufacturing solid-state imaging devices according to claim 2, wherein said pressing member is engaged with a pressure vessel on the rear side of the pressing member via a sealing member disposed on the peripheral edge of the pressing member, pressure fluid is fed between the pressure vessel and said pressing member; and
at said joining step, said pressing member can incline pivoting on substantially the center point of said other one of the under face of said wafer and the upper face of said transparent flat plate.

7. A joining device for joining two planar members aligned opposite each other by applying pressure, comprising:
a fixed table supporting substantially the whole of one of said planar members;
a pressing member supporting substantially the whole of the other of said planar members via an elastic member;
a pressure vessel which is disposed on the rear side of the pressing member and supports the pressing member via a sealing member disposed on the peripheral edge of the pressing member;
a pressing force supplying device which feeds pressure fluid between said pressure vessel and said pressing member and applies a pressing force to said two planar members by way of said fixed table and said pressing member; and
a pressing member supporting device which supports said pressing member to enable the member to incline pivoting on substantially the center point of the surface of the other one of said planar members.
